(19) United States
(12) Patent Application Publication
(10) Pub. No.: US 2023/0197499 A1
(43) Pub. Date: Jun. 22, 2023

(54) TOOL FOR HANDLING SUBSTRATES WITH OVERHEAD SCREEN AND RELEVANT HANDLING METHODS AND EPITAXIAL REACTOR

(71) Applicant: LPE S.P.A., Baranzate (MI) (IT)

(72) Inventors: Silvio Preti, Baranzate (MI) (IT); Stefano Polli, Baranzate (MI) (IT)

(21) Appl. No.: 17/925,344

(22) PCT Filed: May 27, 2021
(86) PCT No.: PCT/IB2021/054627

§ 371 Date: Nov. 15, 2022

(30) Foreign Application Priority Data
May 29, 2020 (IT) 102020000012805

(51) Int. Cl. H01L 21/687

(52) U.S. Cl. CPC H01L 21/68707

(57) ABSTRACT

The tool (4000) for handling substrates (3000) comprises a fork (4100); the fork (4100) comprises two arms (4120, 4140) configured to directly or indirectly grip or support one or more substrates (3000) by applying by contact lateral and/or vertical force when in use; there is provided a screen (4500) fixed or fixable to the fork (4100) so as to be overhanging at distance the substrate(s) (3000) when, in use, it/they is/are gripped or supported by the fork (4100).

### FIELD OF THE INVENTION

The present invention relates to a tool for handling substrates with overhead screen and relevant handling methods, and to an epitaxial reactor using them.

It is premised that, in general, the tool according to the present invention may come into contact with the substrates, so-called “direct handling”, or may come into contact with a substrate support element, so-called “indirect handling”. The most typical embodiments of the present invention are designed for “indirect handling”.

### STATE OF THE ART

In known epitaxial reactors, the substrates to be treated are introduced into a reaction chamber, then the substrates are treated at high temperature (the treatment comprises an epitaxial deposition of semiconductor material on the substrates), finally the treated substrates are extracted from the reaction chamber.

Depending on the case, i.e., in particular depending on the substrate material and the semiconductor material to be deposited, the treatment temperature can vary for example from 600° C. (and even less) to 1700° C. (and even more); the treatment temperature also generally depends on the pressure inside the chamber during treatment. The temperature outside the chamber, in particular the “storage” temperature in the epitaxial reactor, is the ambient temperature, e.g., typically between 20° C. and 30° C.

### ABSTRACT

In order to reduce the processing time, in particular the reactor cycle time, it would be advantageous to introduce the substrates when the chamber is already quite hot (i.e., much higher than the ambient temperature) and/or to extract the substrates when the chamber is still quite hot (i.e., much higher than the ambient temperature); in this way, the temperature inside the chamber can always remain quite high (i.e., not much lower than the process temperature). For example, if epitaxial deposition of monocrystalline silicon carbide on silicon carbide substrates at a pressure of 50÷200 mbar is taken into consideration, the process temperature may be 1500÷1700° C. and it would be advantageous to introduce and/or to extract substrates when the chamber is at a temperature comprised in the range of, for example, 700-1100° C. (or even higher).

However, doing so the substrates would be subjected to thermal shock. Indeed, in the introduction step the temperature of a substrate changes in a very short time (e.g., a few seconds) for example from 25° C. to 900° C. and in the extraction step the temperature of a substrate changes in a very short time (e.g., a few seconds) for example from 900° C. to 25° C. Such a thermal shock can cause problems to the substrates, in particular damage. It should be noted that the thermal shock essentially affects the upper face of the substrates, i.e., the exposed face, and causes a temperature difference between the upper face and lower face of the substrates. The general object of the present invention is to overcome the above problem. Said object is achieved thanks to the method, the tool and the epitaxial reactor having the technical characteristics expressed in the appended claims.

The idea behind the present invention is to provide a tool with a screen placed so as to be overhanging the substrates when, in use, the substrates are handled by the tool.

### LIST OF FIGURES

The present invention shall become more readily apparent from the detailed description that follows to be considered together with the accompanying drawings in which:

FIG. 1 shows a schematic view (which can be considered a top view) of an embodiment of an epitaxial reactor according to the present invention,

FIG. 2A shows a (schematic) top view of an embodiment of a “substrate support device” of the epitaxial reactor of FIG. 1,

FIG. 2B shows a sectional (schematic) view of the “substrate support device” of FIG. 2A,

FIG. 3 shows (schematically) an embodiment of a robot of the epitaxial reactor of FIG. 1,

FIG. 4A shows a three-dimensional view of an embodiment of a tool according to the present invention usable in the epitaxial reactor of FIG. 1,

FIG. 4B shows the tool of FIG. 4A in exploded three-dimensional view,

FIG. 4C shows the tool of FIG. 4A in plane side view,

FIG. 5 shows a possible time diagram of the temperature of a substrate during a process of introduction in the reaction chamber of the epitaxial reactor of FIG. 1, and

FIG. 6 shows a possible time diagram of the temperature of a substrate during a process of extraction from the reaction chamber of the epitaxial reactor of FIG. 1.

As can be easily understood, there are various ways of practically implementing the present invention which is defined in its main advantageous aspects in the appended claims and is not limited either to the following detailed description or to the appended claims.

### DETAILED DESCRIPTION

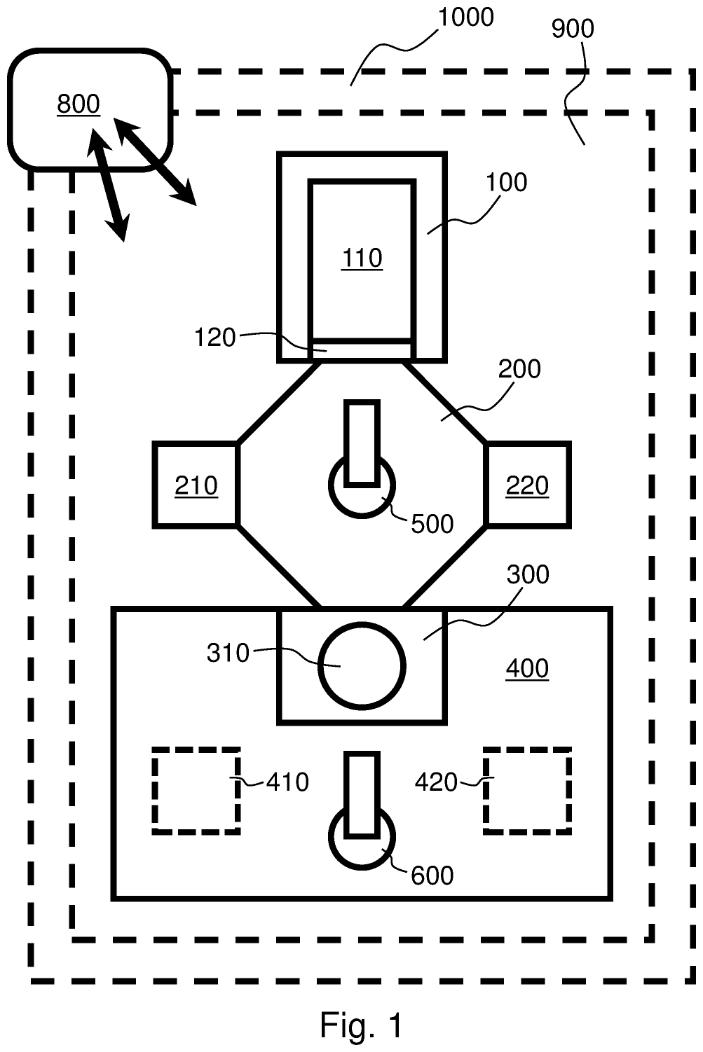

With reference to FIG. 1, an embodiment of an epitaxial reactor 1000 according to the present invention comprising a so-called “treatment assembly” 900.

In FIG. 1, an electronic control unit 800 is shown which, depending on the functions, can be considered part of the epitaxial reactor 1000, i.e., of the entire system, or of the treatment assembly 900, i.e., a sub-system thereof. In general, it is possible for an epitaxial reactor to comprise several electronic control units each dedicated to the control of one or more sub-systems. In the example of FIG. 1, the electronic control unit 800 is arranged to control at least the treatment assembly 900 and, for this purpose, receives and sends electrical signals from and to components of the treatment assembly 900 (this is schematically represented by the two large black arrows).

In general, an epitaxial reactor, including the epitaxial reactor according to the present invention, comprises a control console which can also be considered part of a control unit of the epitaxial reactor.

The treatment assembly 900 consists of four basic components:
a reaction chamber 100 for treating substrates,
a transfer chamber 200 adjacent to the reaction chamber 100,
a “load-lock” chamber 300 adjacent to the transfer chamber 200, and
a loading/unloading chamber 400 adjacent to the “load-lock” chamber 300.

It should be noted that, alternatively, the chambers 200 and 300 could be integrated and constitute a single chamber.

In the example of FIG. 1, the chamber 300 is located inside the chamber 400.

In general, an epitaxial reactor comprises so-called “gate valves” adapted to selectively separate the reactor chambers. In the case of the reactor of FIG. 1, there are provided a first “gate valve” 120 between the chamber 100 and the chamber 200 and a second “gate valve” (not shown in the figure) between the chamber 200 and the chamber 300; in addition, there is provided (but not shown in the figure) a door, preferably hermetically sealed, to allow operators to access the interior of the chamber 400 and put/remove substrates and substrate support devices.

The treatment assembly 900 further comprises an “external robot” 600 and an “internal robot” 500 shown in FIG. 1 with a symbol; the robot 600 is used for transferring treated substrates, untreated substrates and substrate support devices without substrates between the loading/unloading chamber 400 and the load-lock chamber 300; the robot 500 is used for transferring substrate support devices with one or more substrates between the load-lock chamber 300 and the reaction chamber 100 via the transfer chamber 200.

In the reactor of FIG. 1, the substrates are placed on a “substrate support device” prior to a treatment process and are removed from the “substrate support device” after the treatment process; these two operations are performed by the robot 600. In the reactor of FIG. 1, a support device with untreated substrates is transferred from the load-lock chamber 300 to the reaction chamber 100 prior to a treatment process, and the same support device but with treated substrates is transferred from the reaction chamber 100 to the load-lock chamber 300 after the treatment process; these two transfer operations are performed by the robot 500.

The treatment assembly 900 may comprise a cooling station 210 (optional) adjacent to the transfer chamber 200; the cooling station 210 is adapted to contain a substrate support device with one or more substrates after a treatment process.

The treatment assembly 900 may also comprise a pre-heating station 220 (optional) adjacent to the transfer chamber 200; the heating station 220 is adapted to contain a substrate support device with one or more substrates before a treatment process. The load lock chamber 300 comprises a base 310 for supporting a “substrate support device” (with or without substrates).

The loading/unloading chamber 400 has at least a first storage area 410 for treated and untreated substrates and at least a second storage area 420 for substrate support devices without substrates.

As mentioned above, in the reactor of FIG. 1, it is advantageously provided the use of “substrate support devices”; this is a kind of flat tray (in particular of circular shape) with one or more recesses for housing one or more substrates to be treated, typically provided with a radially protruding edge adapted to be gripped or supported.

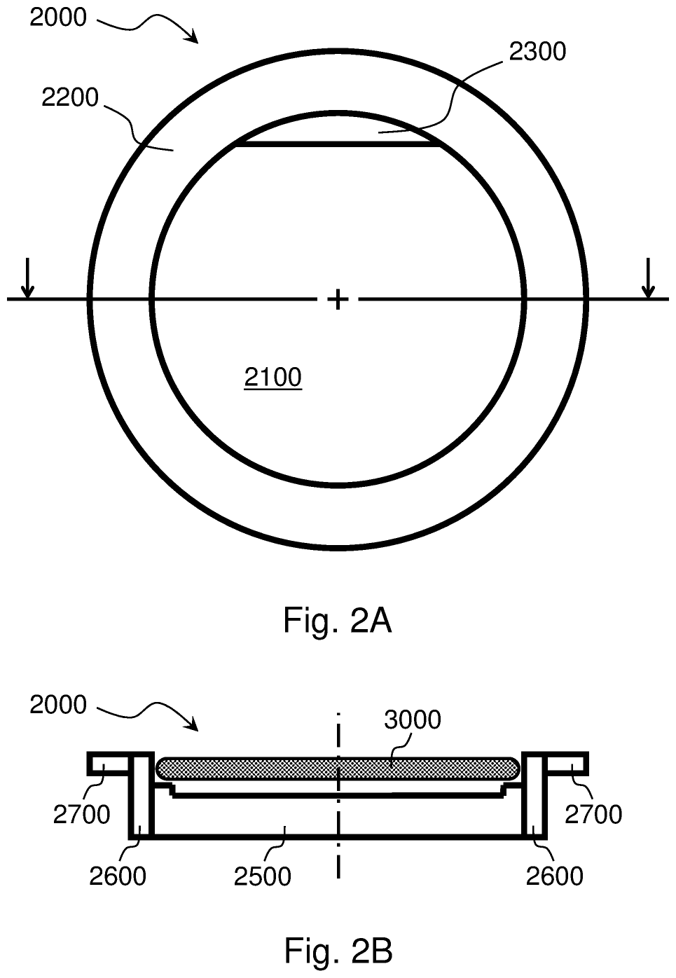

The “substrate support device” 2000 of FIG. 2 has a so-called “pocket” recess 2100, which is (almost) circular in shape to house a substrate (not shown in FIG. 2A and indicated with 3000 in FIG. 2B) substantially the same shape and size as the recess, and a thin edge 2200 radially protruding along its entire perimeter to facilitate the handling of the “substrate support device”. Specifically, FIG. 2 refers to the case where the substrate has a so-called “flat”, and in the recess 2100, an element 2300 may be located at this “flat”; in practice, the element 2300 is typically integrated into the device 2000.

The “substrate support device” 2000 of FIG. 2 can also be described by means of a set of parts as follows (see in particular FIG. 2B). It comprises a plate-like part, simply called “plate”, 2500 of circular shape which has a rest surface adapted to support a substrate 3000; in particular, the rest surface has substantially the same shape and size as the substrate and constitutes the bottom of the recess 2100; the plug 2300 (if any) conceptually overlaps the plate 2500. The device 2000 further comprises a first edge part 2600 which entirely surrounds the plate 2500 and which extends axially so as to constitute the side wall of the recess 2100 (a small part of this wall is constituted by the plug 2300). The device 2000 finally comprises a second edge part 2700 which entirely surrounds the first edge part 2600 and which extends radially; it can be said that the second edge part 2700 is a flange located around the first edge part 2600. Typically, the plate 2500 is at a lower level than the second edge portion 2700. The edge 2200 corresponds substantially to the second edge part 2700. It should be noted that the parts described above can be joined to form one or more single pieces; for example, the parts 2500, 2600 and 2700 can form a single piece or the part 2500 can form a first single piece and the parts 2600 and 2700 can form a second single piece. Furthermore, it should be noted that each of the parts described above can be formed by two or more single pieces mechanically coupled together; an example relating to the plate 2500 is described below.

The internal robot 500 may comprise an articulated arm 510 adapted to handle substrate support devices. The external robot 600 may be similar to the internal robot 500.

The articulated arm 510 comprises a first arm member 512 and a second arm member 516, the first arm member 512 is hinged to the second arm member 516, the first arm member 512 has a first end portion 513 adapted to handle “substrate support devices”, and a second end portion 514 hinged to the second arm member 516.

The articulated arm 510 can also comprise a bedplate 520.

The articulated arm 510 may also comprise a lifting column 511 mounted on the bedplate 520.

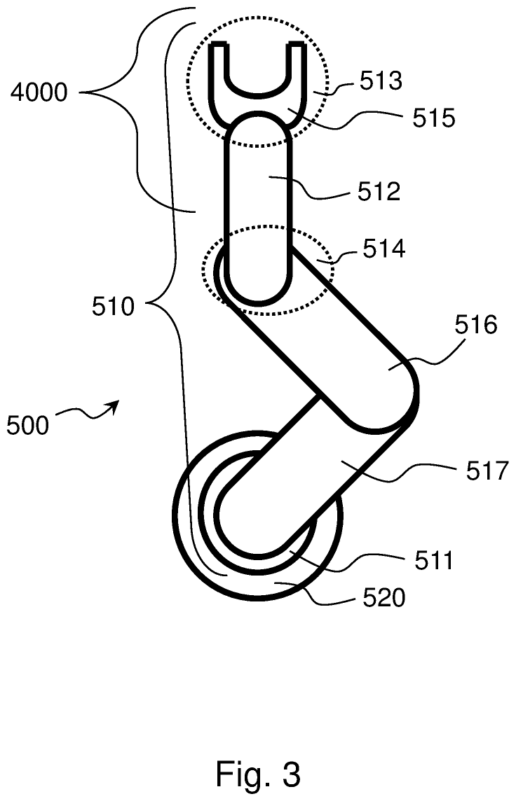

The articulated arm 510 can also comprise a third arm member 517 hinged at a first end to the second arm member 516 and at a second end to the lifting column 511. The first arm member 512 may comprise or be associated with a so-called “end-effector” 515, typically at the first end portion 513, adapted to grip “substrate support devices”; according to the (typical and advantageous) embodiment of FIG. 3, the “end-effector” 515 consists of a “two-tipped fork”.

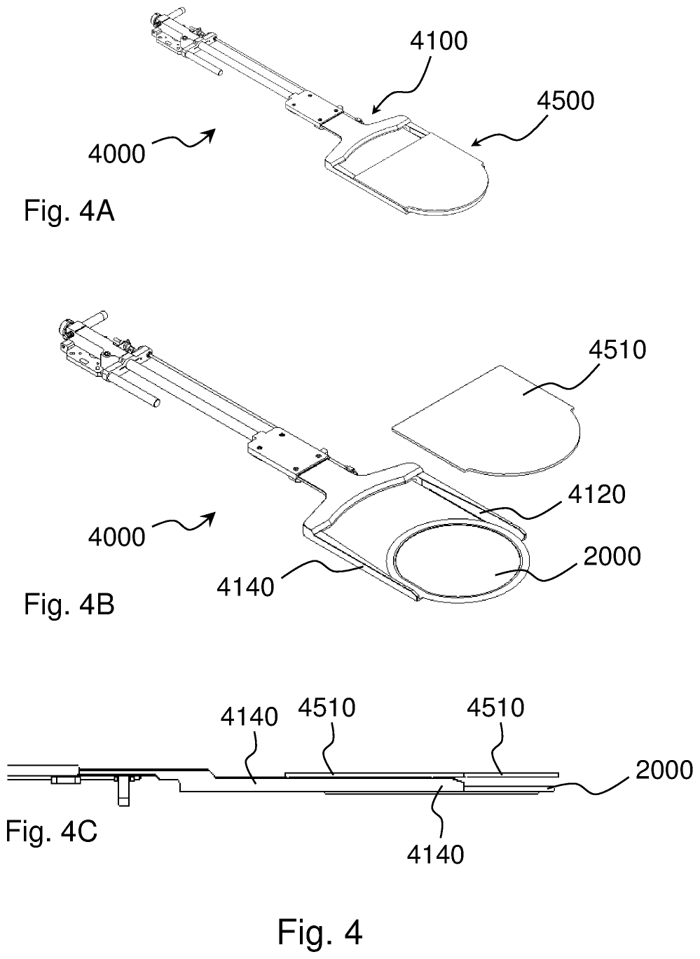

An embodiment of a tool 4000 according to the present invention (usable in the epitaxial reactor of FIG. 1) is shown in detail in FIG. 4. It should be noted that such an embodiment of tool corresponds in FIG. 3 to the combination of part of the arm member 512 coupled to the “end-effector” 515.

Essentially, the tool 4000 of FIG. 4 comprises a screen 4500 placed so as to be overhanging at distance (in particular at uniform distance as will be clear below) one or more substrates 3000 placed on the support element 2000 when the tool 4000 handles the support element 2000 (with one or more resting substrates).

As shown in FIG. 4, the tool 4000 comprises a fork 4100 fixed to the end of a rod-like member 4200. The fork 4100 has two arms 4120 and 4140 for directly gripping or supporting a substrate support element 2000 (visible only in FIG. 4B and FIG. 4C); in particular, the arms 4120 and 4140 have an “L” shaped cross-section such that each shank of the “L” can position itself below the edge 2200 or 2700 (one on one side and one on the other side).

In general, the tool according to the present invention is configured in such a way that the effect of gripping or supporting (a substrate or support element) is obtained, in use, by applying by contact lateral force and/or vertical force (in particular by applying from below vertical force directed upwards). According to preferred embodiments, the contact takes place only between the arms of the fork and a substrate (in particular the edge thereof and/or lower face thereof) or a substrate support element (in particular the edge thereof and/or lower face thereof).

Preferably, the fork 4100 is made of quartz to withstand high temperatures.

In general, the screen is fixed or fixable to the fork, in particular to its arms; moreover, the fork, in particular its two arms, can be configured to allow fixing.

The screen 4500 in FIG. 4 comprises a slab 4510, in particular a flat slab, preferably adapted to be in a horizontal position when, in use, the substrates are gripped or supported by the tool 4000, specifically by the fork 4100, and are in a horizontal position; in this case, the distance between the upper surface of the substrate(s) and the lower surface of the flat slab (which overhangs it or them) is preferably uniform. It should be noted that the slab of the screen may also be pitted at least at the substrates.

According to the embodiment of FIG. 4, the substrates are gripped or supported indirectly by the tool 4000 as they are resting on the element 2000; according to alternative (but less typical) embodiments, they could be gripped or supported directly.

In particular, the slab 4510 is fixed to the arms 4120 and 4140 by, for example, elements of the screen 4500 not shown in the figures (separate elements may be provided to prevent forward/backward (i.e., longitudinal) movements of the slab 4510 with respect to the fork 4100 and to prevent right/left (i.e., transverse) movements of the slab 4510 with respect to the fork 4100); preferably, the slab 4510 and the element 2000 (as well as the substrate(s), if any, supported by the support element) are substantially parallel to each other and placed at a small distance, for example in the range from 3 to 10 mm.

The screen (which is not in contact with the substrate(s)) may be adapted to store heat in such a way as to reduce the thermal shock, or rather to retard the heating of the underlying substrate(s) (when in use) by preventing the transmission of heat by radiation.

The screen (which is not in contact with the substrate(s)) may be adapted to shield underlying substrates (when in use) from infrared radiation by hindering the transmission of heat by conduction and/or convection. It is worth pointing out that for the most typical applications of the present invention (epitaxial reactors for the deposition of semiconductor material, in particular silicon and silicon carbide on substrates between 600° C. and 1700° C.), heat transmission by irradiation mainly involves the infrared light range, but it also occurs to some extent in the visible light range.

A particularly ideal material for the screen, especially for the flat slab is graphite. Particularly suitable sizes for slab thickness are comprised in the range from 1.5 to 3.5 mm.

According to the embodiment of FIG. 4, the fork and the screen are two separate elements and made of different material. However, other embodiments cannot be ruled out. For example, fork and screen could be integrated into a single mechanical piece or into two pieces joined together; such a piece could be made of graphite; alternatively, such a piece could be made of quartz and, for example, the fork could be of transparent quartz and the screen could be of opaque quartz and be welded together.

In the following description, it is assumed for simplicity's sake that the tool 4000 is mechanically coupled and decoupled with a support element 2000 in a very short and negligible time.

However, such operations take some time (e.g., a couple of seconds) and can be described as follows with reference to the tool in FIG. 4.

To obtain a coupling, the fork approaches the support element, and then the arms of the fork slide (forwards) under the edge of the support element until they reach the desired end position; as the arms slide, the screen gradually covers any substrate(s) placed on the support element. Then, the fork rises slightly and its arms rest under the edge of the support element (in this position, the fork can be considered to have gripped the support element); again, the arms push down on the edge and lift the support element.

To obtain a decoupling, the arms of the fork (which are in the desired end position mentioned above, i.e., they grip the support element) lower slightly so as not to rest under the edge of the support element, then slide (backwards) under the edge until they disengage from the support element, and finally the fork moves away from the support element; as the arms slide, the screen gradually uncovers any substrate(s) placed on the support element.

The processes described below can typically and advantageously be carried out using the tools described herein.

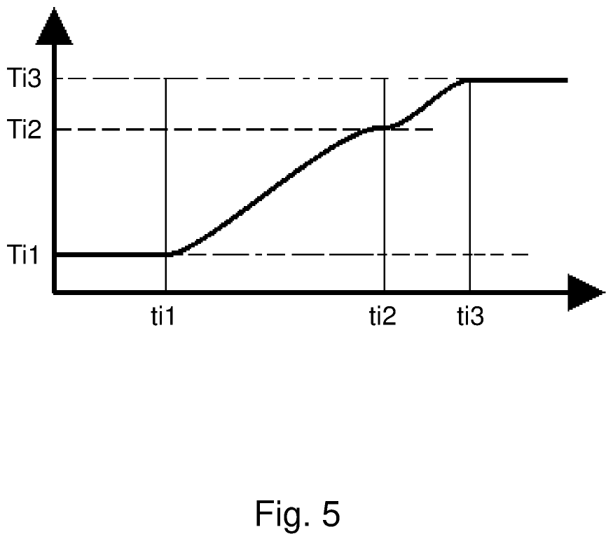

A substrate introduction process according to the present invention may comprise, for example, the steps of (consider for example FIG. 1 and FIG. 5):
I1) adjusting an internal temperature of the reaction chamber 100 to a predetermined temperature below a process temperature (typically prior to the start of a treatment process),
I2) positioning the tool 4000 provided with the screen 4500 at the support element 2000 with substrates to be treated so that the screen 4500 overhangs the substrates to be treated (this can take place, for example, in the load-lock chamber 300),
I3) gripping the support element 2000 by means of the tool 4000,
I4) opening the access hatch 120 of the reaction chamber 100,
I5) moving the tool 4000 with the support element 2000 until the support element 2000 is internal (see reference 110) to the reaction chamber 100,
I6) depositing the support element 2000 in the reaction chamber 100,
I7) moving the tool 4000 without the support element 2000 until the tool 4000 is external to (see reference 200) the reaction chamber 100,
I8) closing the access hatch 120 to the reaction chamber 100, and
I9) adjusting an internal temperature of the reaction chamber 100 to a process temperature.

At this point, the real treatment process can begin.

In the diagram of FIG. 5, a time ti1 corresponds to when, during step I5, the tool 4000 with the substrates is facing the entrance (just outside) of the reaction chamber 100 and is about to enter; the tool 4000, the element 2000 and the substrates are at a temperature Ti1 that corresponds to ambient temperature, i.e., typically between 20° C. and 30° C., for example 25° C.

In the diagram of FIG. 5, there is a temperature Ti3 that corresponds to the predetermined temperature mentioned above. For example, if the process temperature is 1600-1700° C., the temperature Ti3 could typically be between 700° C. and 1100° C., for example 900° C.

A time ti2 corresponds to when, during step I7, the tool 4000 without the substrates has just exited the reaction chamber 100 and the screen 4500 no longer overhangs the substrates; approximately at time ti2, the hatch 120 closes.

In the time interval between time ti1 and time ti2, the substrates undergo heating; this heating is slowed by the presence of the screen 4500 above the substrates; thus, the thermal shock is reduced. At time ti2, the substrates reach a temperature Ti2 that is typically lower than the temperature Ti3, for example equal to 60÷80% of the temperature Ti3 expressed in degrees centigrade, i.e., Ti2=[0.6÷0.8]*Te3.

In the time interval between time ti2 and a time ti3, the substrates undergo a further heating; this further heating cannot be a source of thermal shock because the temperature difference between the chamber and the substrates is relatively small. According to typical cases, the time interval between time ti1 and time ti2 may be 20-60 s.

According to typical cases, the time interval between time ti2 and time ti3 may be 10-20 s.

It should be noted that the heating of the reaction chamber 100 to carry out the treatment process can start already at time ti2 for example by reactivating the heating system of the reactor. However, such reactivation has little effect on the diagram of FIG. 5 (in particular on time ti3) since the interval ti2-ti3 is of the order of 10 s while the response time of the heating system of the reactor is of the order of a minute (in other words, several minutes are required in order to bring the chamber and its contents for example from 900° C. to 1650° C.).

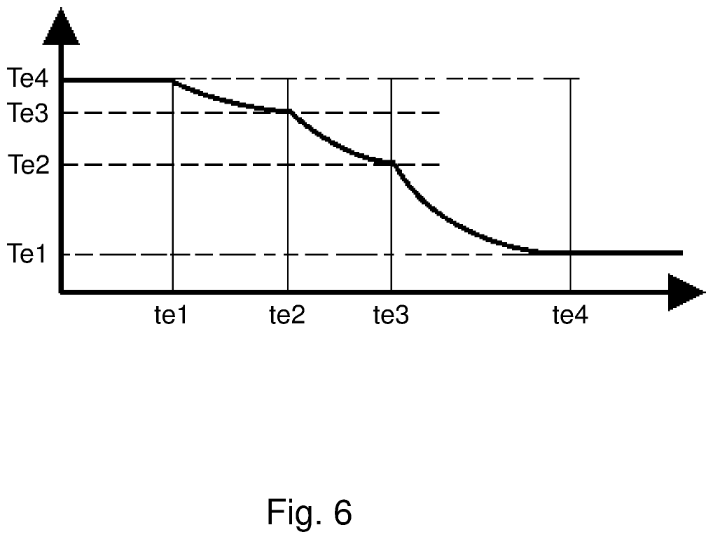

A substrate extraction process according to the present invention may comprise, for example, the steps of (consider for example FIG. 1 and FIG. 6):
E1) adjusting an internal temperature of the reaction chamber 100 to a predetermined temperature below a process temperature (typically after the end of a treatment process),
E2) opening the access hatch 120 to the reaction chamber 100,
E3) positioning the tool 4000 provided with the screen 4500 until it is internal (see reference 110) to the reaction chamber 100 and at the support element 2000 with treated substrates so that the screen 4500 overhangs the treated substrates,
E4) gripping the support element (2000) by means of the tool 4000,
E5) moving the tool 4000 with the support element 2000 until the tool 4000 is external to (see reference 200) the reaction chamber 100, and
E6) closing the access hatch 120 to the reaction chamber 100.

At this point, for example, the support element 2000 with substrates may be placed in the load-lock chamber 300, and, thereafter, the reaction chamber 100 may be loaded with new substrates to be treated.

In the diagram of FIG. 6, a time te1 corresponds to when, during step E3, the tool 4000 without substrates is facing the entrance (just outside) of the reaction chamber 100 and is about to enter; the tool 4000 with the screen 4500 is at ambient temperature, i.e. typically between 20° C. and 30° C., for example 25° C., the element 2000 and the substrates (as well as the entire reaction chamber 100) are at a temperature Te1 that corresponds to the predetermined temperature mentioned above, typically in the said case between 700° C. and 1100° C., e.g. 900° C.

A time te2 corresponds to when, during step E5, the tool 4000 with the substrates has just exited the reaction chamber 100; at approximately time te2, the hatch 120 closes.

During the time interval between time te1 and time te2, the screen 4500 overhangs the substrates. It should be noted that the screen 4500 is made in such a way as to heat up rapidly when it enters the reaction chamber 100 and therefore the initial cooling of the substrates during the time interval between the time te1 and the time te2 is very small; a temperature Te2 at the time te2 may be for example equal to 85÷95% of the temperature Te1 expressed in degrees centigrade, that is Te2=[0.85÷0.95]*Te1.

A time te3 corresponds to when the tool 4000 leaves the substrates (placed on the support element 2000) for example in the load-lock chamber 300. The diagram in FIG. 6, is irrespective of the time necessary for the tool to enter the load-lock chamber 300, leave the element 2000 and exit the load-lock chamber 300; this time could be a few seconds (for example 4÷5 s) and is much lower than the time of permanence of the element 2000 in the load-lock chamber (for example 50÷300 s). During the time interval between time te2 and time te3, the screen 4500 overhangs the substrates and an initial cooling of the substrates takes place; this cooling is slow because the screen 4500 continues to keep the substrates warm due to its thermal inertia; therefore, the thermal shock is small. At the time te3 there will be a temperature Te3 that can be for example equal to 30÷50% of the temperature Te1 expressed in degrees centigrade, that is Te3=[0.3÷0.5]*Te1.

A time te4 corresponds to when the element 2000 with the substrates in the load-lock chamber 300 has completely cooled to a temperature Te4 that corresponds to ambient temperature, typically between 20° C. and 30° C., for example 25° C. During the time interval between time te3 and time te34, a second and final cooling of the substrates takes place; this second and final cooling cannot be a source of thermal shock because the temperature difference between the load-lock and the substrates is relatively small.

According to typical cases, the time interval between time te1 and time te2 may be 20-60 s.

According to typical cases, the time interval between time ti2 and time ti3 may be 20-60 s.

According to typical cases, the time interval between time ti3 and time ti4 may be 50-300 s.

The diagrams in FIG. 5 and FIG. 6 indicate the average temperature of the upper face of the substrates; the lower face of the substrates is substantially at the temperature of the support element; at steady state, the upper face and lower face of each substrate are at the same temperature. The support element has a high thermal inertia and therefore its temperature varies slowly, but still varies both when the element is introduced into the reaction chamber and when the element is extracted from the reaction chamber. Therefore, the use of a screen according to the present invention causes the temperature difference between the faces of the substrates to be reduced.

The reactor 1000 comprises a tool 4000 for handling substrates, which is an embodiment of the present invention.

The tool 4000 is used to introduce and extract substrates into and from the reaction chamber 100.

In general, one can speak of transferring substrates (advantageously substrates placed on support elements) between the reaction chamber and one or more “positioning stations”. In the example of FIG. 1, the most typical “positioning station” is the load-lock chamber 300, but any chamber 210 and/or any chamber 220 may also be such.

As will be understood from the foregoing, the present invention allows substrates to be loaded and unloaded into and from the reaction chamber without reducing the temperature of the reaction chamber too much, but with limited thermal shock for the substrates. Thus, the productivity of the reactor increases.

1. Tool for handling substrates, comprising a fork;
wherein said fork comprises two arms configured to directly or indirectly grip or support one or more substrates by applying by contact lateral or vertical or inclined force when in use;
wherein the tool comprises a screen fixed or fixable to said fork so as to be overhanging at distance said one or more substrates when, in use, said one or more substrates are gripped or supported by said fork.

2. Tool for handling substrates according to claim 1, wherein said screen comprises a slab, in particular a flat slab.

3. Tool for handling substrates according to claim 2, wherein said slab is adapted to be in a horizontal position when, in use, said one or more substrates are gripped or supported by the fork and are in a horizontal position.

4. Tool for handling substrates according to claim 1, wherein said screen is adapted to store heat.

5. Tool for handling substrates according to claim 1, wherein said screen is adapted to shield from infrared radiation.

6. Tool for handling substrates according to claim 1, wherein said screen is made of graphite.

7. Tool for handling substrates according to claim 1, wherein said fork is configured to directly grip or support a substrate support element by applying by contact lateral or vertical or inclined force to said substrate support element when in use.

8. Tool for handling substrates according to claim 1, wherein said screen is fixed or fixable to said fork, in particular to the two arms of said fork.

9. Tool for handling substrates according to claim 1, wherein said fork is made of quartz.

10. Epitaxial reactor comprising a tool for handling substrates according to claim 1.

11. Epitaxial reactor according to claim 10, comprising a reaction chamber, wherein said tool is adapted to be used to introduce or extract substrates into or from said reaction chamber.

12. Epitaxial reactor according to claim 10, comprising a substrate positioning station, wherein said tool is adapted to be used to bring substrates from or to said positioning station, and wherein said positioning station is a load-lock chamber or a cooling station or a heating station.

13. Epitaxial reactor according to claim 10, adapted to handle substrates placed on substrate support elements.

14. Method for introducing substrates into a reaction chamber of an epitaxial reactor, comprising the steps of:
I1) adjusting an internal temperature of said reaction chamber to a predetermined temperature below a process temperature,
I2) positioning a tool provided with a screen at a support element with one or more substrates to be treated so that said screen is overhanging said one or more substrates to be treated,
I3) gripping said support element by means of said tool,
I4) opening an access hatch to said reaction chamber,
I5) moving said tool with said support element until said support element is internal to said reaction chamber,
I6) depositing said support element in said reaction chamber,
I7) moving said tool without said support element until said tool is external to said reaction chamber,
I8) closing said access hatch to said reaction chamber; and
I9) adjusting an internal temperature of said reaction chamber to a process temperature.

15. Method for extracting substrates in a reaction chamber of an epitaxial reactor, comprising the steps of:
E1) adjusting an internal temperature of said reaction chamber to a predetermined temperature below a process temperature,
E2) opening an access hatch to said reaction chamber,
E3) positioning a tool provided with a screen until the tool is internal to said reaction chamber and at a support element with one or more treated substrates so that said screen is overhanging said one or treated more substrates,
E4) gripping said support element by means of said tool,
E5) moving said tool with said support element until said tool is external to said reaction chamber, and
E6) closing said access hatch to said reaction chamber.
